(19) United States
(12) Patent Application Publication
(10) Pub. No.: US 2024/0243198 A1
(43) Pub. Date: Jul. 18, 2024

(54) SEMICONDUCTOR DEVICE, METHODS OF MANUFACTURING SEMICONDUCTOR DEVICE, AND SEMICONDUCTOR MODULE

(71) Applicant: Renesas Electronics Corporation, Tokyo (JP)

(72) Inventors: Hiroshi YANAGIGAWA, Tokyo (JP); Yasutaka NAKASHIBA, Tokyo (JP); Kazuhisa MORI, Tokyo (JP); Koichi HASEGAWA, Tokyo (JP)

(21) Appl. No.: 18/407,125

(22) Filed: Jan. 8, 2024

(30) Foreign Application Priority Data
Jan. 13, 2023 (JP) 2023-004026

(51) Int. Cl. H01L 29/78; G01K 7/01; H01L 23/00; H01L 29/06; H01L 29/66

(52) U.S. Cl. CPC H01L 29/7813; G01K 7/01; H01L 24/45; H01L 24/48; H01L 29/0696; H01L 29/66734; H01L 2224/45124; H01L 2224/45144; H01L 2224/48464; H01L 2224/48472; H01L 2924/13091

(57) ABSTRACT

According to this present application, a reliability of a semiconductor device can be improved. The semiconductor device has a first region where a MOSFET is formed, and a second region where a temperature sensor transistor is formed. A body region is formed in a semiconductor substrate of the first region, and a base region is formed in the semiconductor substrate of the second region. A source region is formed in the body region and an emitter region is formed in the base region. A first column region is formed in the semiconductor substrate located below the body region, and a second column region is formed in the semiconductor substrate located below the base region.

### CROSS-REFERENCE TO RELATED APPLICATIONS

The disclosure of Japanese Patent Application No. 2023-004026 filed on Jan. 13, 2023, including the specification, drawings and abstract is incorporated herein by reference in its entirety.

### BACKGROUND

This invention relates to a semiconductor device, a manufacturing method of the semiconductor device, and a semiconductor module, particularly a temperature sensor transistor or a sense MOSFET are embedded thereof.

In the semiconductor device in which a high withstand voltage is required, semiconductor element such as a power MOSFET (Metal Oxide Semiconductor Field Effect Transistor) with a trench gate type in which the gate electrode is embedded inside the trench are applied. In such the semiconductor device, the temperature sensor transistor or the sense MOSFET may be built in as an element for overheat protection function.

For example, for example, Japanese Patent Laid-Open No. 2009-289791 (Patent Document 1) discloses a technology that applies an NPN bipolar transistor as the temperature sensor transistor and connects a plurality of NPN bipolar transistors in a Darlington connection.

### SUMMARY

When integrating a power MOSFET and a temperature sensor transistor, from the perspective of simplifying the manufacturing process, it is desirable to manufacture part of the structure of the temperature sensor transistor by the same process as the process of manufacturing part of the structure of the power MOSFET, such as a p-type body region and an n-type source region.

However, if the structure of the power MOSFET is changed in response to market demands, such as further reduction of on-resistance, the structure of the temperature sensor transistor will be also changed. Therefore, depending on contents of change, the detection accuracy of the temperature sensor transistor may be deteriorated, and there is a risk that the reliability of the semiconductor device may decrease.

Other objects and novel features will become apparent from the description of this specification and the accompanying drawings.

The typical ones of the embodiments disclosed in the present application will be briefly described as follows.

A manufacturing method of a semiconductor device according to one embodiment involves the semiconductor device with a first region where a MOSFET is formed and a second region where a first temperature sensor transistor is formed. The manufacturing method of the semiconductor device includes the steps of: (a) preparing a first conductivity type semiconductor substrate having an upper surface and a bottom surface, (b) forming a trench in the semiconductor substrate in the first region on the upper side of the semiconductor substrate, (c) forming a gate dielectric film inside the trench, (d) forming a gate electrode inside the trench via the gate dielectric film, (e) forming a body region of a second conductivity type opposite to the first conductivity type in the semiconductor substrate close to the upper surface of the semiconductor substrate in the first region so as to be shallower than a depth of the trench, and forming a first base region of the second conductivity type in the semiconductor substrate in the second region, (f) forming a source region of the first conductivity type in the body region and forming a first emitter region of the first conductivity type in the first base region, (g) forming a first column region of the second conductivity type in the semiconductor substrate in the first region located below the body region and forming a second column region of the second conductivity type in the semiconductor substrate in the second region located below the first base region. The semiconductor substrate, the trench, the gate dielectric film, the gate electrode, the body region, the source region, and the first column region of the first region each configures a part of the MOSFET, and the semiconductor substrate, the first base region, the first emitter region, and the second column region of the second region each configures a part of the first temperature sensor transistor.

A semiconductor device according to one embodiment is the semiconductor device with a first region where a MOSFET is formed and a second region where a first temperature sensor transistor is formed. The semiconductor device includes a first conductivity type semiconductor substrate having an upper surface and a bottom surface, a trench formed in the semiconductor substrate close to the upper surface of the semiconductor substrate in the first region, a gate dielectric film formed inside the trench, a gate electrode formed inside the trench via the gate dielectric film, a body region of a second conductivity type opposite to the first conductivity type formed in the semiconductor substrate close to the upper surface of the semiconductor substrate in the first region so as to be shallower than a depth of the trench, a source region of the first conductivity type formed in the body region, a first column region of the second conductivity type formed in the semiconductor substrate in the first region located below the body region, a first base region of the second conductivity type formed in the semiconductor substrate close to the upper surface of the semiconductor substrate in the second region, a first emitter region of the first conductivity type formed in the first base region, and a second column region of the second conductivity type formed in the semiconductor substrate in the second region located below the first base region. The semiconductor substrate, the trench, the gate dielectric film, the gate electrode, the body region, the source region, and the first column region of the first region each configures a part of the MOSFET, and the semiconductor substrate, the first base region, the first emitter region, and the second column region each configures a part of the first temperature sensor transistor, and the second column region has a same depth and a same impurity concentration as the first column region.

A semiconductor module according to one embodiment includes a first semiconductor chip having a MOSFET and a sense MOSFET, and a second semiconductor chip stacked on an upper surface of the first semiconductor chip via an insulating film and having a control circuit for controlling a gate voltage of the MOSFET.

The first semiconductor chip has a source electrode electrically connected to the source region of the MOSFET, and at a location different from where the second semiconductor chip is placed, an opening is provided in the insulating film, and the source electrode exposed at the opening constitutes a source pad. The sense MOSFET has the same structure as the MOSFET and is provided between the source pad of the MOSFET and an outer edge of the first semiconductor chip, and has a function of monitoring a current value of the MOSFET.

According to one embodiment, the reliability of the semiconductor device can be improved.

### BRIEF DESCRIPTION OF THE DRAWINGS

FIG. 1 is a plan view showing a semiconductor device according to a first embodiment.

FIG. 2 is a main portion plan view showing the semiconductor device according to the first embodiment.

FIG. 3 is a main portion plan view showing the semiconductor device according to the first embodiment.

FIG. 4 is a cross-sectional view showing the semiconductor device according to the first embodiment.

FIG. 5 is an equivalent circuit diagram showing a temperature sensor transistor with Darlington connection according to the first embodiment.

FIG. 6 is a cross-sectional view showing the temperature sensor transistor with Darlington connection according to the first embodiment.

FIG. 7 is a cross-sectional view showing the temperature sensor transistors with Darlington connection according to the studied example.

FIG. 8 is a graph showing impurity concentration profiles of the temperature sensor transistor in the first embodiment and the studied example.

FIG. 9 is a graph showing an experimental data by the inventors.

FIG. 10 is a graph showing an experimental data by the inventors.

FIG. 11 is a cross-sectional view showing a manufacturing step of the semiconductor device according to the first embodiment.

FIG. 12 is a cross-sectional view showing a manufacturing step of the semiconductor device performed after the step shown in FIG. 11.

FIG. 13 is a cross-sectional view showing a manufacturing step of the semiconductor device performed after the step shown in FIG. 12.

FIG. 14 is a cross-sectional view showing a manufacturing step of the semiconductor device performed after the step shown in FIG. 13.

FIG. 15 is a cross-sectional view showing a manufacturing step of the semiconductor device performed after the step shown in FIG. 14.

FIG. 16 is a cross-sectional view showing a manufacturing step of the semiconductor device performed after the step shown in FIG. 15.

FIG. 17 is a cross-sectional view showing a manufacturing step of the semiconductor device performed after the step shown in FIG. 16.

FIG. 18 is a cross-sectional view showing a manufacturing step of the semiconductor device performed after the step shown in FIG. 17.

FIG. 19 is a cross-sectional view showing a manufacturing step of the semiconductor device performed after the step shown in FIG. 18.

FIG. 20 is a cross-sectional view showing a manufacturing step of the semiconductor device performed after the step shown in FIG. 19.

FIG. 21 is a cross-sectional view showing a manufacturing step of the semiconductor device performed after the step shown in FIG. 20.

FIG. 22 is a plan view showing a semiconductor module according to a second embodiment.

FIG. 23 is a cross-sectional view showing a semiconductor module according to a second embodiment.

FIG. 24 is a plan view showing a positional relationship between a source pad and the groove of the semiconductor device according to the second embodiment.

FIG. 25 is a plan view showing the temperature characteristics of the semiconductor device according to the second embodiment.

FIG. 26 is a cross-sectional view showing method for manufacturing the groove according to the second embodiment.

### DETAILED DESCRIPTION

In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present application intersect each other and are orthogonal to each other. In the present application, the Z direction is described as a vertical direction, a height direction, or a thickness direction of a certain structure. In addition, the expression “plan view” used in this application means that the plane formed by the X direction and the Y direction is a “plane” and the “plane” is viewed from the Z direction.

### First Embodiment

### Structure of a Semiconductor Device

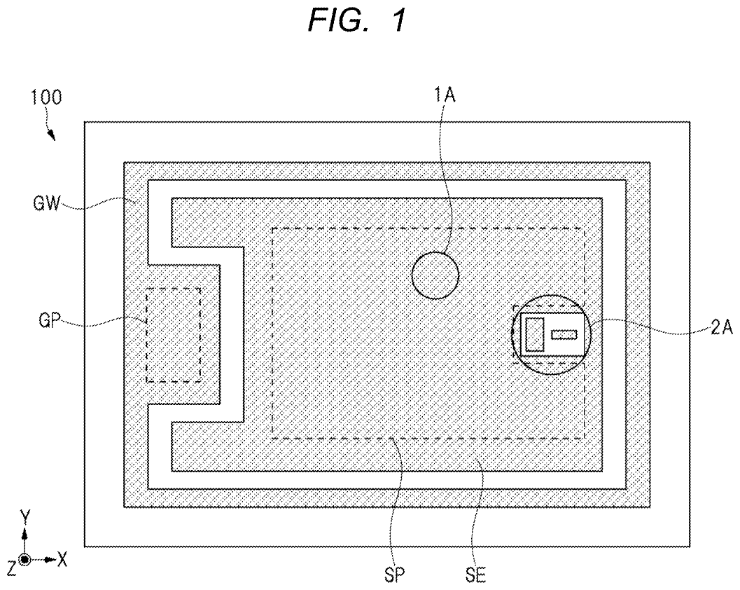

The semiconductor device 100 in the first embodiment will be described below with referring FIGS. 1 to 6. FIG. 1 is a plan view showing the semiconductor device 100. As shown in FIG. 1, most of the semiconductor device 100 is covered by a source electrode SE. A gate wiring GW is formed to surround the source electrode SE in the plan view.

Although not shown in FIG. 1, the source electrode SE and the gate wiring GW are covered by an insulating film such as a polyimide film. On the source electrode SE and the gate wiring GW, openings are provided in a part of the insulating film. The source electrode SE and the gate wiring GW exposed at the openings configure a source pad SP and the gate pad GP. By connecting an external connection member to the source pad SP and the gate pad GP, the semiconductor device 100 is electrically connected to other semiconductor chips, lead frames, or wiring substrates. The external connection member is, for example, a bonding wire made of gold, copper, or aluminum alloy, or a clip like a copper plate.

The semiconductor device 100 has a cell region where a main semiconductor element such as a power MOSFET is formed, and a sensor region where a plurality of temperature sensor transistors is formed. A region 1A shown in FIG. 1 indicates a part of the cell region, and a region 2A shown in FIG. 1 indicates a part of the sensor region.

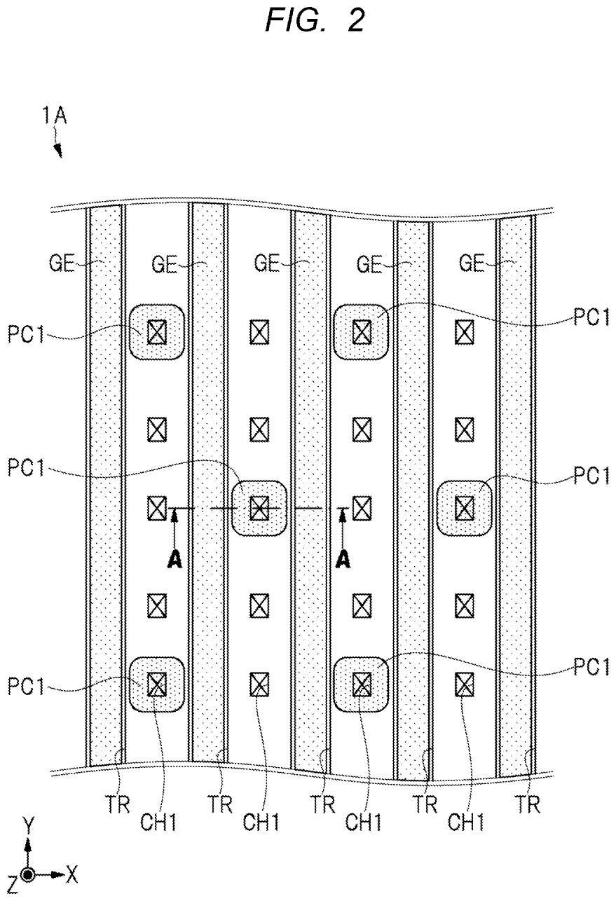

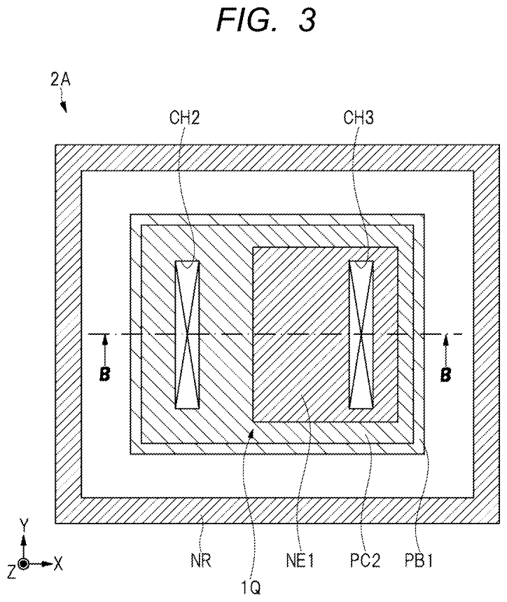

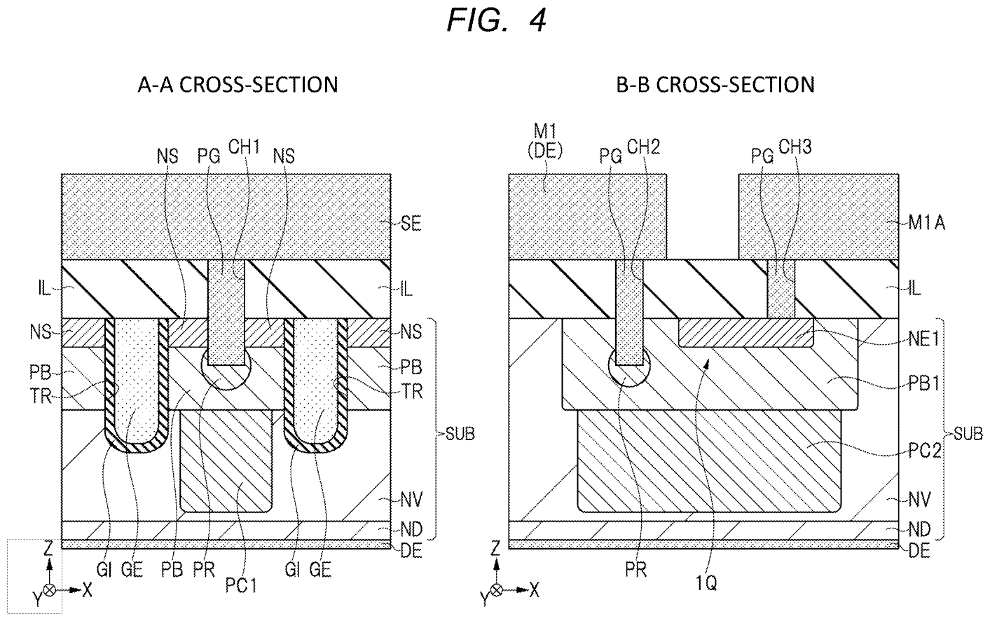

FIG. 2. is a plan view of the main portion corresponding to the region 1A. FIG. 3. is a plan view of the main portion corresponding to the region 2A. FIG. 4 shows a cross-sectional view along the line A-A in FIG. 2 and a cross-sectional view along the line B-B in FIG. 3.

### Power MOSFET of Region 1A

The structure of the power MOSFET in region 1A will be explained below with referring FIGS. 2 and 4. The power MOSFET includes a gate dielectric film GI, a gate electrode GE, a body region PB, a source region NS, a high concentration diffusion region PR, a column region PC1, and a semiconductor substrate SUB (drift region NV, drain region ND).

As shown in FIG. 2, a plurality of trenches TR is formed in the semiconductor substrate SUB. The plurality of trenches TR is formed in a stripe pattern, each extending in the Y direction and adjacent to each other in the X direction. the gate electrode GE is formed inside the trench TR. A plurality of holes CH1 is arranged along the extension direction of the trench TR with spaced apart from each other. Through the plurality of holes CH1, the source electrode SE and the source region NS and the body region PB are electrically connected.

As shown in FIG. 4, the semiconductor device 100 includes the n-type semiconductor substrate SUB with an upper surface and a bottom surface. The semiconductor substrate SUB is made of silicon. The semiconductor substrate SUB has a low concentration n-type drift region NV and an n-type drain region ND with a higher impurity concentration than the drift region NV. The drain region ND is, for example, an n-type silicon substrate. The drift region NV is an n-type silicon layer grown by introducing phosphorus (P) by, for example, an epitaxial growth method on the above-mentioned n-type silicon substrate. In this application, such a laminated body is explained as the semiconductor substrate SUB.

Note that, the drain of the power MOSFET is configured of the drift region NV and the drain region ND. Therefore, in some case, the semiconductor substrate SUB is described as the drain of the power MOSFET.

In the semiconductor substrate SUB close to the upper surface, the trench TR reaching a predetermined depth from the upper surface of the semiconductor substrate SUB is formed. The depth of the trench TR is, for example, 0.5 micrometers or more and 2 micrometers or less. Inside the trench TR, the gate dielectric film GI is formed. The gate dielectric film GI is, for example, a silicon oxide film and has a thickness of, for example, 10 nm or more and 50 nm or less.

Inside the trench TR, the gate electrode GE is formed via the gate dielectric film GI so as to fill the inside of the trench TR. The gate electrode GE is, for example, a polycrystalline silicon film in which n-type impurities are implanted.

In the semiconductor substrate SUB close to the upper surface, the p-type body region (impurity region) PB is formed in the semiconductor substrate SUB so as to be shallower than the depth of the trench TR. The n-type source region (impurity region) NS is formed in the body region PB. The source region NS has a higher impurity concentration than the drift region NV.

The p-type column region (impurity region) PC1 is formed in the semiconductor substrate SUB located below the body region PB. The column region PC1 has a higher impurity concentration than the body region PB and is in contact with the body region PB. As shown in FIG. 2, a plurality of column regions PC1 is provided at equal interval in the extension direction (Y direction) of the trench TR. Also, a plurality of column regions PC1 is arranged in a staggered manner. By arranging the p-type column region PC1 two-dimensionally in the n-type drift region NV, the surroundings of the column region PC1 can be depleted, and the breakdown voltage can be improved.

An equilateral triangle is formed by lines connecting the centers of each of the plurality of column regions PC1. This makes it easier to uniform the depletion layer extending from each column regions PC1, and it is easier to fully deplete between each column regions PC1.

A drain electrode DE is formed on the bottom surface of the semiconductor substrate SUB. The drain electrode DE is made of a single layer of metal film such as an aluminum film, a titanium film, a nickel film, a gold film or a silver film, or a laminated film made by appropriately laminating these metal films. The drift region NV, the drain region ND, and the drain electrode DE are not only formed in the region 1A, but also in the region 2A. A drain voltage (power supply voltage) is supplied from the outside of the semiconductor device 100 to the semiconductor substrate SUB (drain region ND, drift region NV) via the drain electrode DE.

An interlayer insulating film IL is formed on the upper surface of the semiconductor substrate SUB to cover the trench TR. The interlayer insulating film IL is, for example, a laminated film of a thin silicon oxide film and a thick silicon oxide film containing boron and phosphorus (BPSG: Boro Phospho Silicate Glass film). The thickness of the interlayer insulating film IL is, for example, 700 nm or more and 1200 nm or less.

A hole CH1 is formed in the interlayer insulating film IL, the source region NS, and the body region PB. The bottom of the hole CH1 is located inside the body region PB. Near the bottom of the hole CH1, a high concentration diffusion region (impurity region) PR is formed in the body region PB. The high concentration diffusion region PR has a higher impurity concentration than the body region PB. The high concentration diffusion region PR is mainly provided to reduce the contact resistance with the plug PG.

A plug PG is formed inside the hole CH1. The plug PG includes a barrier metal film and a conductive film formed on the barrier metal film. The barrier metal film is, for example, a laminated film of a titanium film and a titanium nitride film formed on the titanium film. The conductive film is, for example, a tungsten film.

Although not shown here, hole is also formed on a part of the gate electrode GE, and a plug PG is also formed inside this hole.

The source electrode SE is formed on the interlayer insulating film IL. The source electrode SE is electrically connected to the source region NS, the body region PB, and high concentration diffusion region PR through the hole CH1 (plug PG), and supplies these regions with a source voltage. Although not shown here, the gate wiring GW, which is formed in the same manufacturing step as the source electrode SE, is also formed on the interlayer insulating film IL. The gate wiring GW is electrically connected to the gate electrode GE through the plug PG, and supplies the gate electrode GE with a gate voltage.

Such the source electrode SE and the gate wiring GW include a barrier metal film and a conductive film formed on the barrier metal film. The barrier metal film is, for example, a TiW film. The conductive film is, for example, an aluminum alloy film to which copper or silicon has been added. The aluminum alloy film is the main conductor film of the source electrode SE and the gate wiring GW, and is sufficiently thicker than the barrier metal film.

### Temperature Sensor Transistor in Region 2A

The structure of the temperature sensor transistor 1Q in the region 2A will be explained with referring FIGS. 3 and 4. The temperature sensor transistor 1Q includes a base region PB1, emitter region NE1, high concentration diffusion region PR, a column region PC2, and the semiconductor substrate SUB (drift region NV, drain region ND), etc.

As shown in FIG. 4, in the semiconductor substrate SUB close to the upper surface, the p-type base region (impurity region) PB1 is formed. In the base region PB1, the n-type emitter region (impurity region) NE1 is formed.

In the semiconductor substrate SUB located below the base region PB1, the p-type column region (impurity region) PC2 is formed. The column region PC2 has a higher impurity concentration than the base region PB1 and is in contact with the base region PB1.

The hole CH2 is formed in the interlayer insulating film IL and the base region PB1. The bottom of the hole CH2 is located inside the base region PB1. Near the bottom of the hole CH2, a high concentration diffusion region PR is formed in the base region PB1. Also, in the interlayer insulating film IL, a hole CH3 is formed to reach the emitter region NE1. Plugs PG are formed inside each of the holes CH2 and CH3.

A wiring M1A is formed on the interlayer insulating film IL. The wiring M1A is electrically connected to the emitter region NE1 through the hole CH3 (plug PG). Also, on the interlayer insulating film IL, a wiring M1, which is formed in the same manufacturing step as the wiring M1A, is also formed. The wiring M1 is electrically connected to the base region PB1 through the hole CH2 (plug PG).

The base region PB1 is formed in the same manufacturing step as the body region PB, has a same depth as the body region PB, and has a same impurity concentration as the body region PB. The emitter region NE1 is formed in the same manufacturing step as the source region NS, has a same depth as the source region NS, and has a same impurity concentration as the source region NS. The column region PC2 is formed in the same manufacturing step as the column region PC1, has a same depth as the column region PC1, and has a same impurity concentration as the column region PC1.

As shown in FIG. 3, in a plan view, the column region PC2 is included within the base region PB1, and the emitter region NE1 is included within the column region PC2.Also, in a plan view, the temperature sensor transistor 1Q is surrounded by an n-type high concentration diffusion region (impurity region) NR formed in the semiconductor substrate SUB. The high concentration diffusion region NR is provided to electrically isolate the temperature sensor transistor 1Q from other elements.

The temperature sensor transistor 1Q constitutes an NPN bipolar transistor with the emitter region NE1 as the emitter, the base region PB1 and the column region PC2 as the base, and the semiconductor substrate SUB (drift region NV, drain region ND) as the collector.The main current path of the temperature sensor transistor 1Q is a path leading to the semiconductor substrate SUB via the base region PB1 and the column region PC2 located directly under the emitter region NE1 from the emitter region NE1.

In case of using the temperature sensor transistor 1Q as a temperature sensor alone, the wiring M1 is connected to the semiconductor substrate SUB by a plug formed in a hole not shown in the figures. That is, the wiring M1 is electrically connected to the drain electrode DE via the above-mentioned plug and the semiconductor substrate SUB.

The temperature sensor may be configured by Darlington-connecting the plurality of temperature sensor transistors to improve detection accuracy.

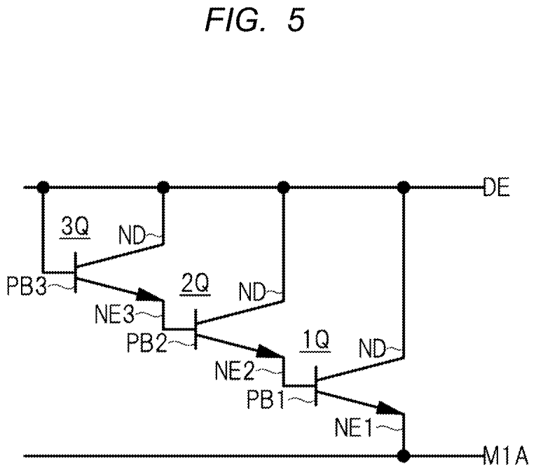

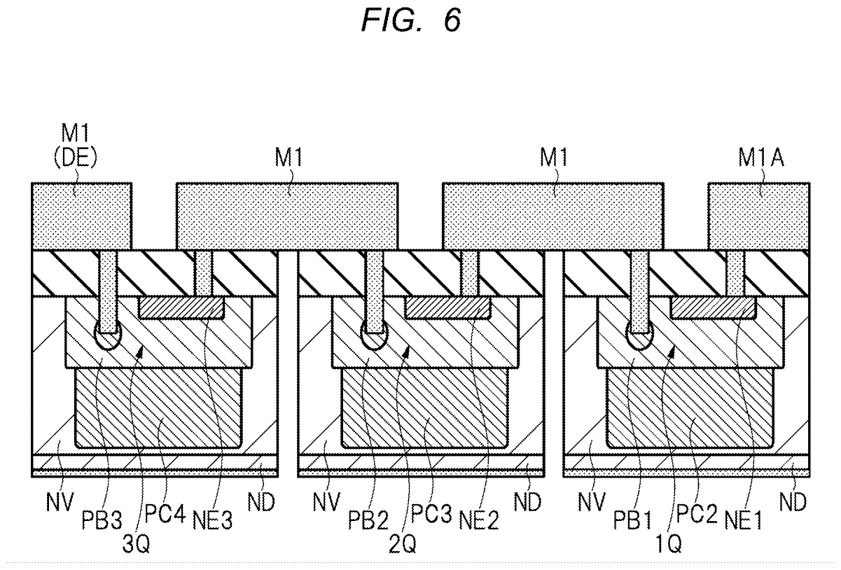

FIGS. 5 and 6 are equivalent circuit diagrams and cross-sectional views showing three Darlington-connected temperature sensor transistors 1Q to 3Q. The temperature sensor transistors 1Q to 3Q are each formed in the semiconductor substrate SUB of region 2A and are surrounded by the high concentration diffusion region NR of FIG. 3.

The cross-sectional structure and planar structure of the temperature sensor transistors 2Q and 3Q are the same as the cross-sectional structure and planar structure of the temperature sensor transistor 1Q, except for the different reference letters attached. That is, the temperature sensor transistor 2Q includes a base region PB2, an emitter region NE2, the high concentration diffusion region PR, a column region PC3, and the semiconductor substrate SUB (drift region NV, drain region ND), etc. The temperature sensor transistor 3Q includes a base region PB3, an emitter region NE3, the high concentration diffusion region PR, a column region PC4, and the semiconductor substrate SUB (drift region NV, drain region ND), etc.

Furthermore, the base regions PB2 and PB3 are formed in the same manufacturing step as the base region PB1, have the same depth as the base region PB1, and have the same impurity concentration as the base region PB1. The emitter regions NE2 and NE3 are formed in the same manufacturing step as the emitter region NE1, have the same depth as the emitter region NE1, and have the same impurity concentration as the emitter region NE1. The column regions PC3 and PC4 are formed in the same manufacturing step as the column region PC2, have the same depth as the column region PC2, and have the same impurity concentration as the column region PC2.

The base region PB1 and the emitter region NE2 are electrically connected by the wiring M1. The base region PB2 and the emitter region NE3 are electrically connected by another wiring M1. The base region PB3 is further electrically connected to another wiring M1.

The wiring M1 connected to the base region of the temperature sensor transistor, which is the first stage of the Darlington connection, is connected to the semiconductor substrate SUB by a plug formed in a hole not shown in the figures, and is electrically connected to the drain electrode DE. Here, the wiring M1 connected to the base region PB3 is electrically connected to the drain electrode DE.

### Studied Example and Main Features of this Application

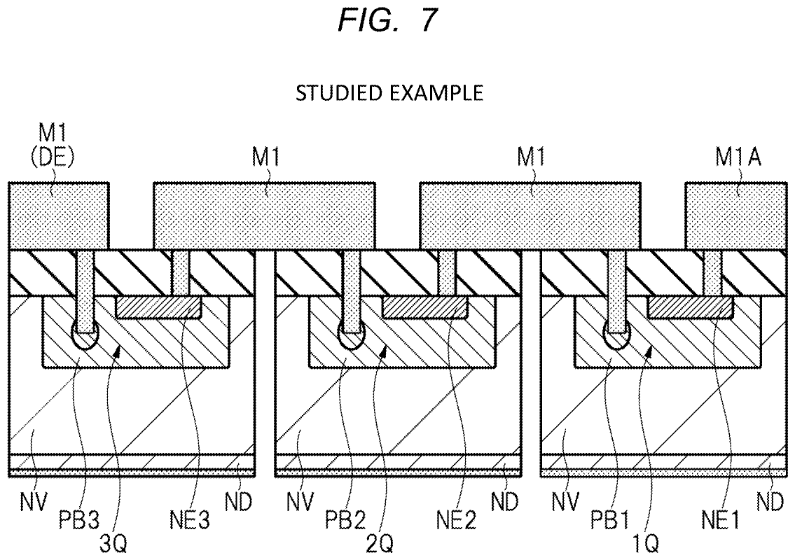

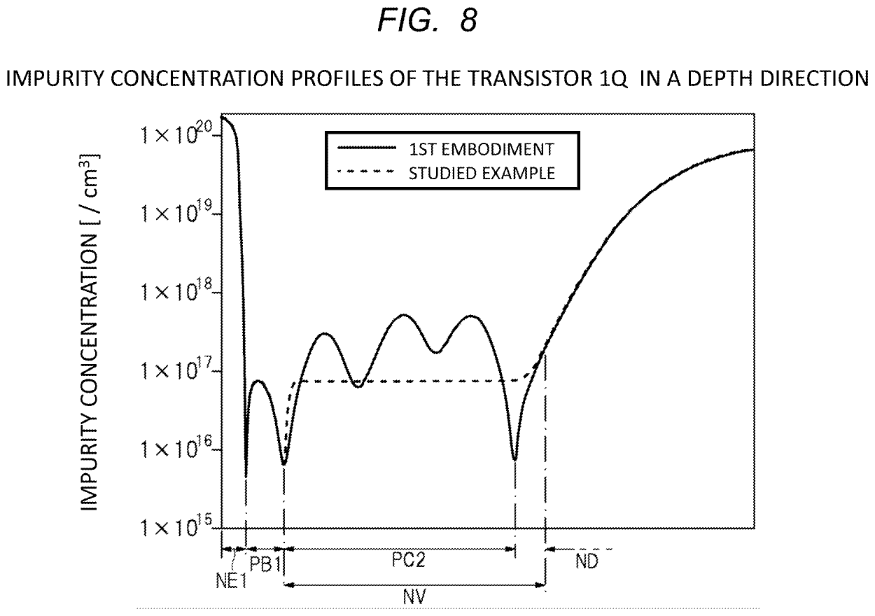

FIG. 7 is a cross-sectional view showing the temperature sensor transistors 1Q to 3Q in the studied example by the inventors of this application. FIG. 8 is a graph showing impurity concentration profiles of the temperature sensor in the first embodiment and the studied example.

As shown in FIG. 7, the temperature sensor transistors 1Q to 3Q in the studied example have the same structure as the temperature sensor transistors 1Q to 3Q in the first embodiment, except that the column regions PC2 to PC4 with high impurity concentration are not formed.

As mentioned above, the base region PB1 is formed in the same manufacturing step as the body region PB to suppress the increase in manufacturing cost. Here, when trying to reduce the on-resistance of the power MOSFET, it is considered to form the body region PB shallowly and to thin the impurity concentration of the body region PB. In that case, the base region PB1 is also formed shallowly, and the impurity concentration of the base region PB1 also becomes thin.

According to the study by the inventors of this application, when the on-resistance was reduced in the studied example, it was found that the temperature coefficient at 25 degree Celsius to 150 degree Celsius becomes −7.6 mV/degree Celsius, and the temperature coefficient at 150 degree Celsius to 200 degree Celsius becomes −3.3 mV/degree Celsius. Generally, at high temperatures, the junction leakage current of the PN junction increases, so the temperature coefficient tends to deteriorate.

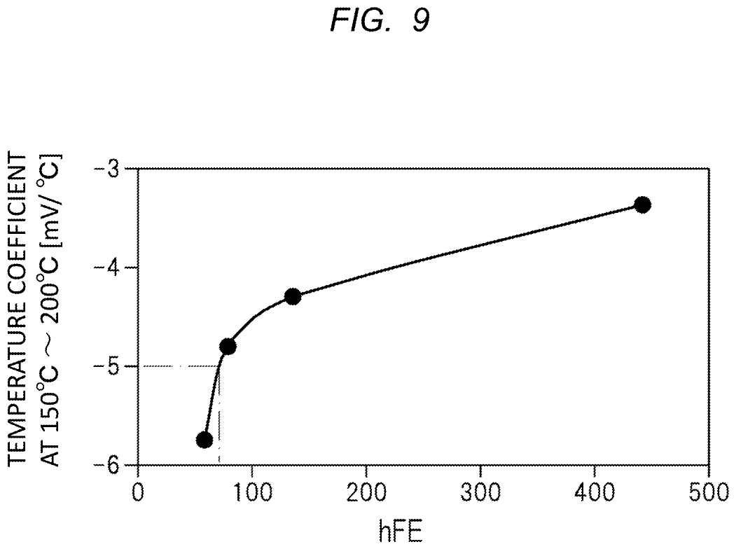

Furthermore, a high hFE, which is the ratio of collector current Ic to base current Ib (Ic/Ib), can also lead to a deterioration in the temperature coefficient. FIG. 9 is a graph showing the relationship between hFE and the temperature coefficient at 150 to 200 degree Celsius. In order to maintain the temperature coefficient at, for example, −5.0 mV/degree Celsius or less, it is necessary for hFE to be approximately 60 or less.

In the case of a Darlington connection as shown in FIG. 5, the current amplified by hFE times in the temperature sensor transistor 3Q is input to the base region PB2 of the temperature sensor transistor 2Q. The current further amplified by hFE times in the temperature sensor transistor 2Q is input to the base region PB1 of the temperature sensor transistor 1Q. In other words, the output current is amplified by the power of N of hFE, depending on a number (N) of temperature sensor transistors used. The more the number (N) of temperature sensor transistors used, the more detailed temperature detection can be achieved, but the temperature coefficient tends to deteriorate, and the detection accuracy tends to decrease. Therefore, it is very important to reduce the hFE of a single temperature sensor transistor.

In the first embodiment, in order to reduce hFE, temperature sensor transistors 1Q to 3Q have the column regions PC2 to PC4 as part of the base regions PB1 to PB3. And, as shown in FIG. 8, the impurity concentration of the column regions PC2 to PC4 is higher than that of the base regions PB1 to PB3.

Furthermore, a depth of the column regions PC2 to PC4 is deeper than a depth of the base regions PB1 to PB3. The depth of the column regions PC2 to PC4 is, for example, 3.0 micrometers or more and 3.5 micrometers or less, and the depth of the base regions PB1 to PB3 is, for example, 0.5 micrometers or more and 1.0 micrometers or less. In other words, the distance from the bottom surface of the base regions PB1 to PB3 to the bottom surface of the column regions PC2 to PC4 is longer than the distance from the upper surface (upper surface of the base regions PB1 to PB3) of the semiconductor substrate SUB to the bottom surface of the base regions PB1 to PB3.

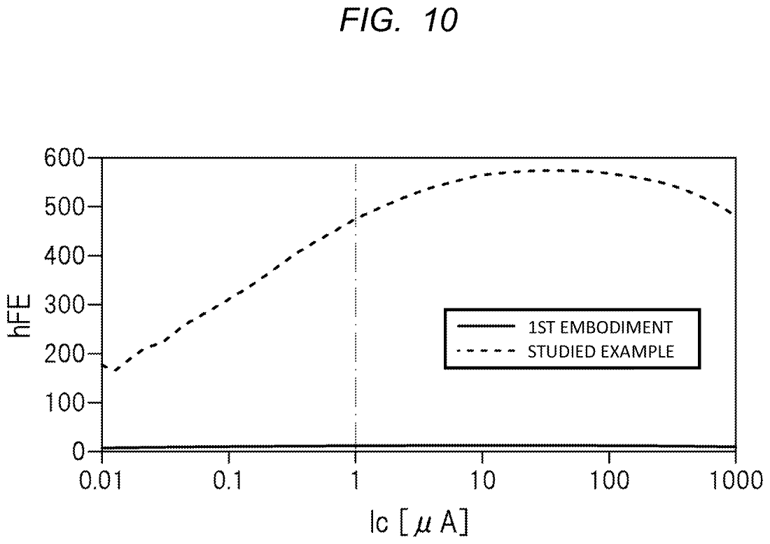

FIG. 10 is a graph showing the relationship between hFE and collector current Ic when temperature sensor transistors 1Q to 3Q are connected in Darlington. As shown in FIG. 10, in the studied example, hFE increases as the collector current Ic increases, but in the first embodiment, hFE is almost constant even if the collector current Ic increases. For example, when the collector current Ic is 1 μA, the hFE of the studied example is about 460, but the hFE of the first embodiment is about 14. Also, when calculating the temperature coefficient of the first embodiment at high temperatures referring to the graph in FIG. 9, the temperature coefficient becomes about −6.9 mV/degree Celsius.

Thus, according to the first embodiment, the deterioration of the detection accuracy of the temperature sensor transistors 1Q to 3Q can be suppressed, which can improve the reliability of the semiconductor device 100.

Furthermore, by making the manufacturing step of the column regions PC2 to PC4 the same as the manufacturing step of the column region PC1 of the power MOSFET, the increase in manufacturing cost can be suppressed.

### Manufacturing Method of the Semiconductor Device

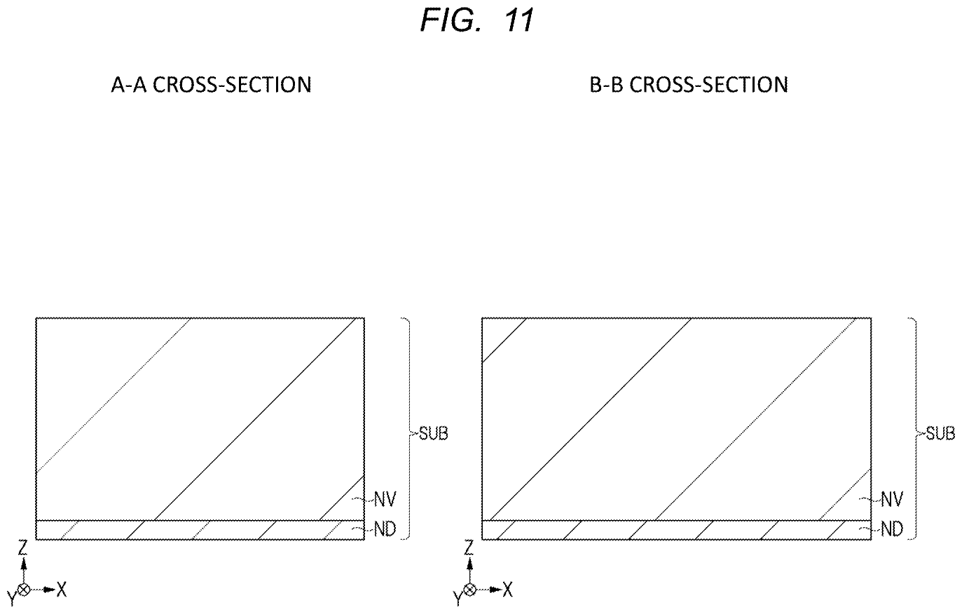

The manufacturing steps included in the manufacturing method of the semiconductor device 100 will be explained below with reference to FIGS. 11 to 21. In the following, the regions 1A (A-A cross section) and 2A (B-B cross section) corresponding to FIG. 4 will be explained.

As showin in FIG. 11, the n-type semiconductor substrate SUB having the upper surface and the bottom surface is prepared. As mentioned above, the semiconductor substrate SUB is, for example, a laminate of an n-type silicon substrate and an n-type silicon layer grown by introducing phosphorus (P) by epitaxial growth on the n-type silicon substrate. The n-type silicon substrate becomes the drain region ND, and the n-type silicon layer becomes the drift region NV.

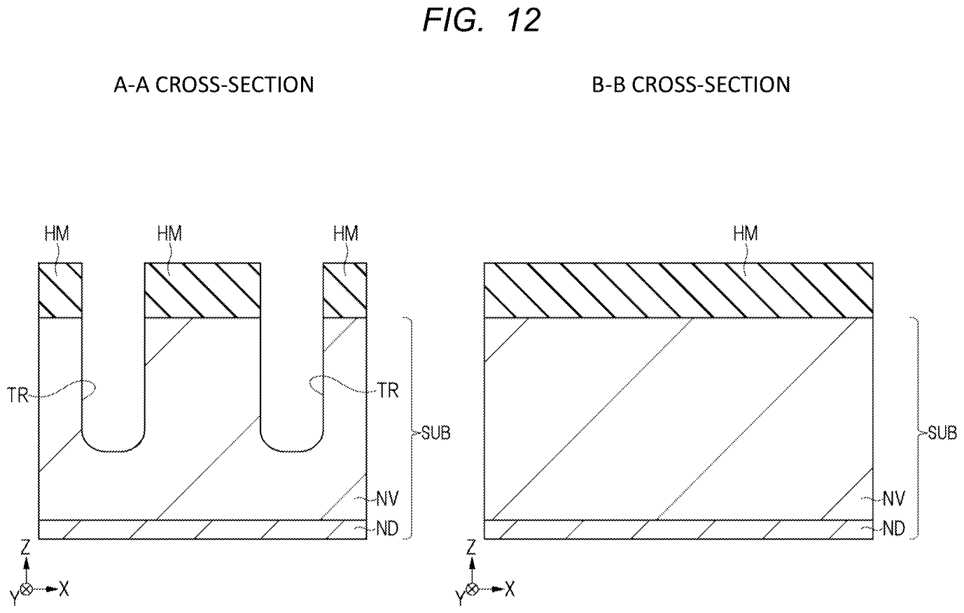

As shown in FIG. 12, the trench TR is formed in the semiconductor substrate SUB in the region 1A close to the upper surface of the semiconductor substrate SUB.

First, a silicon oxide film is formed on the upper surface of the semiconductor substrate SUB, for example, by the CVD (Chemical Vapor Deposition) method. Next, by patterning the silicon oxide film, a hard mask HM having a pattern that selectively opens the semiconductor substrate SUB in the region 1A is formed. Next, by performing anisotropic etching with the hard mask HM as a mask, the trench TR is formed in the semiconductor substrate SUB exposed from the hard mask HM. After that, the hard mask HM is removed by isotropic etching using an aqueous solution containing hydrofluoric acid.

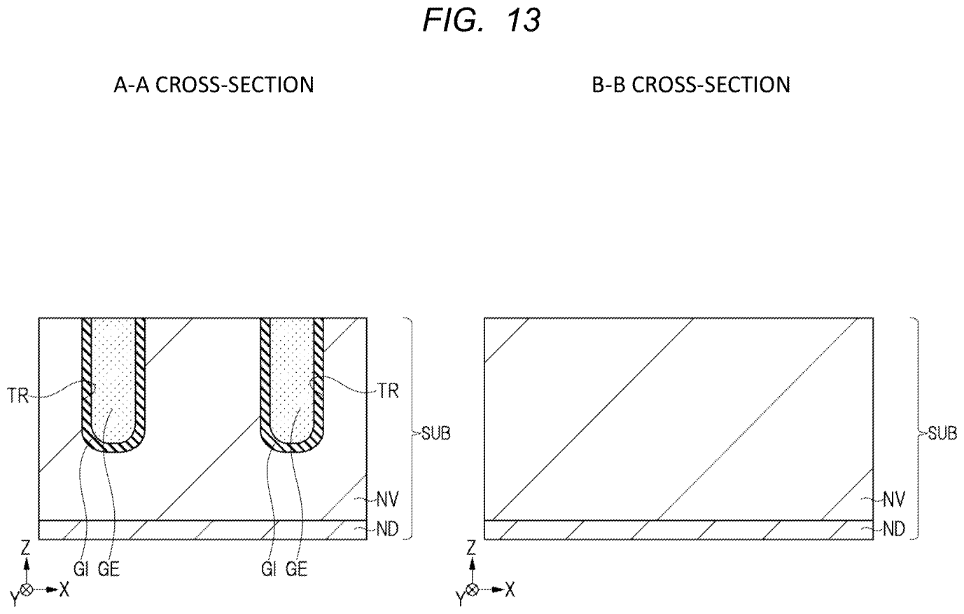

As shown in FIG. 13, a gate electrode GE is formed inside the trench TR via the gate dielectric film GI.

First, the gate dielectric film GI is formed inside the trench TR and on the upper surface of the semiconductor substrate SUB, for example, by thermal oxidation. Next, a conductive film is formed on the gate dielectric film GI, for example, by the CVD method. The conductive film is, for example, an n-type polysilicon film. Next, anisotropic etching is performed on the conductive film. This removes the conductive film outside the trench TR. The conductive film remaining inside the trench TR becomes the gate electrode GE. Next, the gate dielectric film GI outside the trench TR is removed by isotropic etching using an aqueous solution containing hydrofluoric acid.

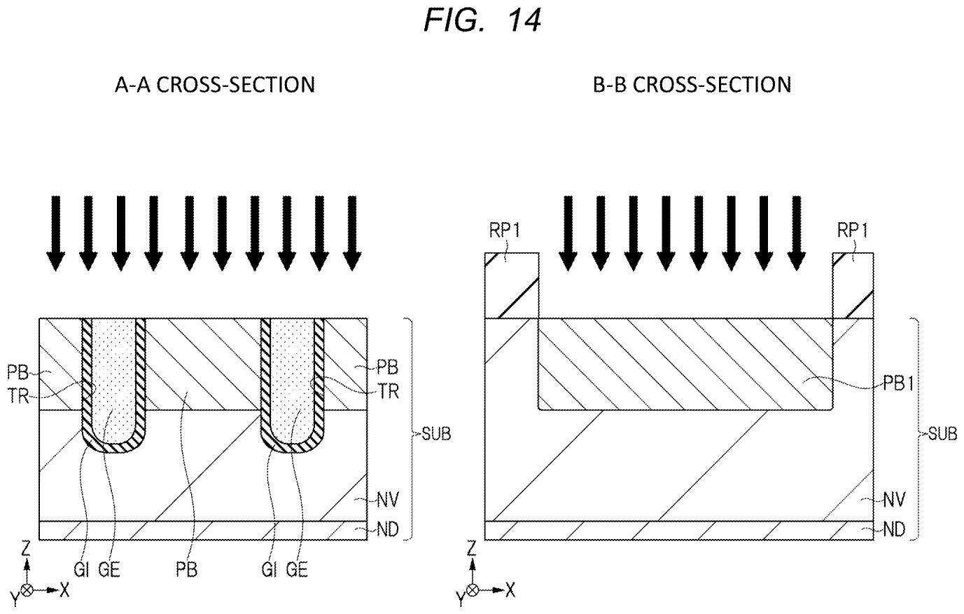

As shown in FIG. 14, the p-type body region PB is formed in the semiconductor substrate SUB close to the upper surface of the semiconductor substrate SUB in the region 1A, and the base region PB1 is formed in the semiconductor substrate SUB in the region 2A.

First, a resist pattern RP1 is formed on the upper surface of the semiconductor substrate SUB. The resist pattern RP1 has a pattern that selectively opens region 1A and a part of region 2A. Then, by performing ion-implantation using the resist pattern RP1 as a mask, the body region PB and the base region PB1 are formed in the semiconductor substrate SUB. In this ion-implantation, boron (B) is used as an impurity. The body region PB is formed to be shallower than the depth of the trench TR. Thereafter, the resist pattern RP1 is removed by an ashing process.

In the same manufacturing step as the manufacturing step of the body region PB and the base region PB1, the base regions PB2 and PB3 are also formed in the semiconductor substrate SUB of region 2A.

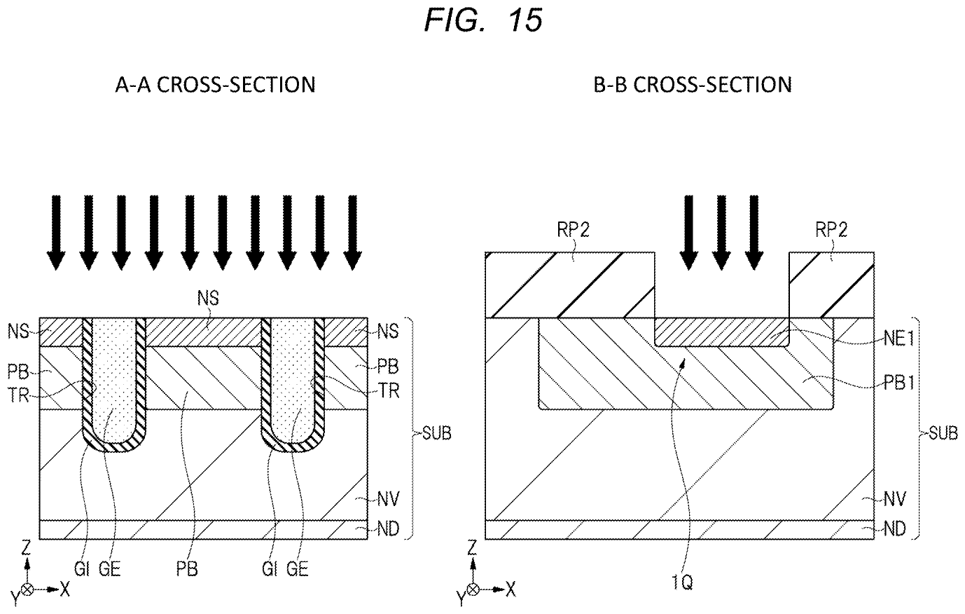

As shown in FIG. 15, the n-type source region NS is formed in the body region PB, and the n-type emitter region NE1 is formed in the base region PB1.

First, a resist pattern RP2 is formed on the upper surface of the semiconductor substrate SUB. The resist pattern RP2 has a pattern that selectively opens region 1A and a part of region 2A. Then, by performing ion-implantation using the resist pattern RP2 as a mask, the source region NS is formed in the body region PB, and the emitter region NE1 is formed in the base region PB1. In this ion-implantation, arsenic (As) is used as an impurity. The source region NS and the emitter region NE1 are formed to be shallower than the depth of the body region PB and the base region PB1, respectively. Thereafter, the resist pattern RP2 is removed by an ashing process.

In the same manufacturing step as the manufacturing step of the source region NS and the emitter region NE1, the emitter regions NE2 and NE3 are also formed in the base regions PB2 and PB3 of region 2A.

Thereafter, a heat treatment is performed on the semiconductor substrate SUB to activate the impurities contained in the body region PB, the base regions PB1 to PB3, the source region NS, and the emitter regions NE1 to NE3.

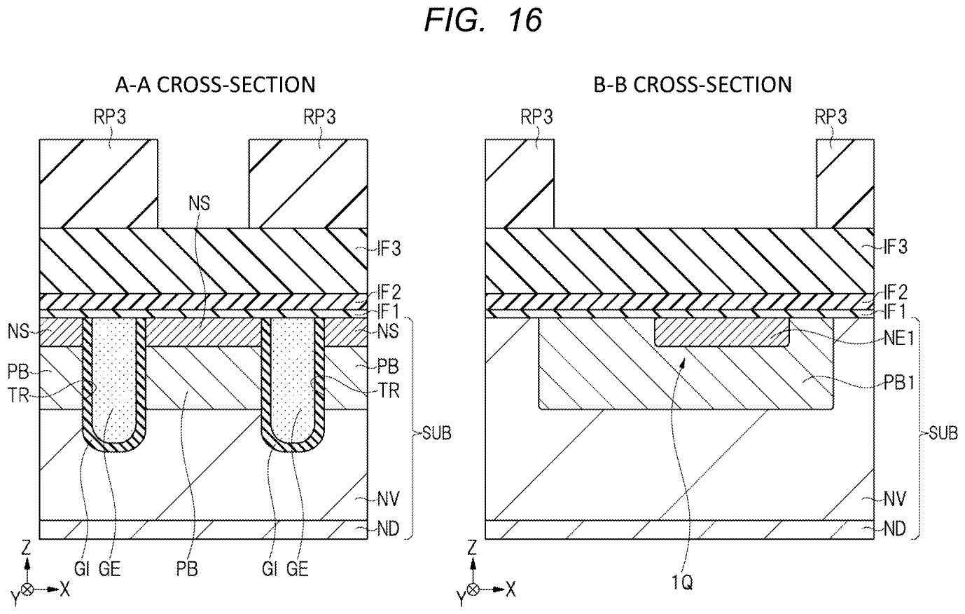

As shown in FIG. 16, insulating films IF1 to IF3 and a resist pattern RP3 are formed on the upper surface of the semiconductor substrate SUB.

First, an insulating film IF1 made of, for example, a silicon oxide film is formed on the upper surface of the semiconductor substrate SUB by, for example, a CVD method. Then, an insulating film IF2 made of, for example, a silicon nitride film is formed on the insulating film IF1 by, for example, a CVD method. Then, an insulating film IF3 made of, for example, a silicon oxide film is formed on the insulating film IF2 by, for example, a CVD method. The thickness of the insulating film IF3 is thicker than the thickness of each of the insulating films IF1 and IF2. Then, a resist pattern RP3 is formed on the insulating film IF3. The resist pattern RP3 has a pattern that selectively opens a part of region 1A and a part of region 2A.

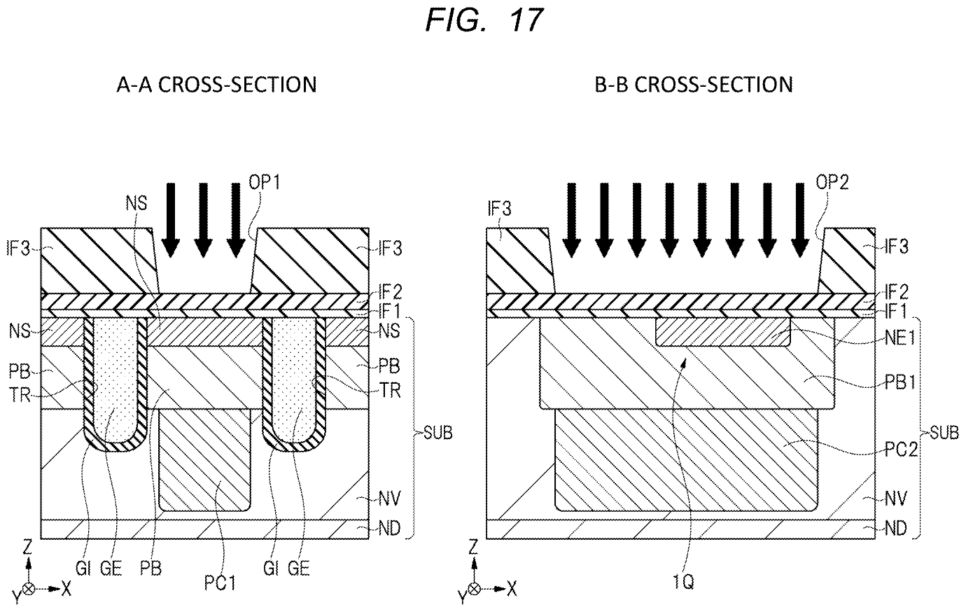

As shown in FIG. 17, the p-type column region PC1 is formed in the semiconductor substrate SUB of region 1A located below the body region PB, and the p-type column region PC2 is formed in the semiconductor substrate SUB of region 2A located below the base region PB1.

First, by performing anisotropic etching using the resist pattern RP3 as a mask, an opening OP1 is formed in the insulating film IF3 located on the body region PB, and an opening OP2 is formed in the insulating film IF3 located on the base region PB1. In this case, the insulating film IF2 functions as an etching stopper. Thereafter, the resist pattern RP3 is removed by an ashing process.

In the patterning of the insulating film IF3 in the region 2A, in a plan view, the end of the opening OP2 is positioned so as to overlap with the base region PB1 and not to overlap with the emitter region NE1. In other words, in a plan view, the end of the opening OP2 is positioned on the base region PB1 located between the emitter region NE1 and the semiconductor substrate SUB. By setting the position of the opening OP2 in this way, the column region PC2 can be formed at a position included in the base region PB1 in a plan view.

Next, ion-implantation is performed using the insulating film IF3 as a mask so as to pass through the insulating films IF2 and IF1 inside the openings OP1 and OP2. In this ion-implantation, boron (B) is used as an impurity, for example. As a result, the column region PC1 is formed in the semiconductor substrate SUB in the region 1A, and the column region PC2 is formed in the semiconductor substrate SUB in the region 2A. This ion-implantation is performed several times while changing the implantation energy. In the first embodiment, this ion-implantation is performed three times. At this time, the impurity concentration profile of the region 2A becomes as shown in FIG. 8.

Subsequently, the insulating films IF3, IF2, and IF1 are sequentially removed by performing an isotropic etching process using an aqueous solution containing hydrofluoric acid or an aqueous solution containing phosphoric acid.

The column regions PC3 and PC4 are also formed in the semiconductor substrate SUB in the region 2A by the same manufacturing step as the manufacturing step of the column regions PC1 and PC2.

At this time, the column regions PC2 to PC4 are each included in the base regions PB1 to PB3 in a plan view. Also, the emitter regions NE1 to NE3 are each included in the column regions PC2 to PC4 in a plan view.

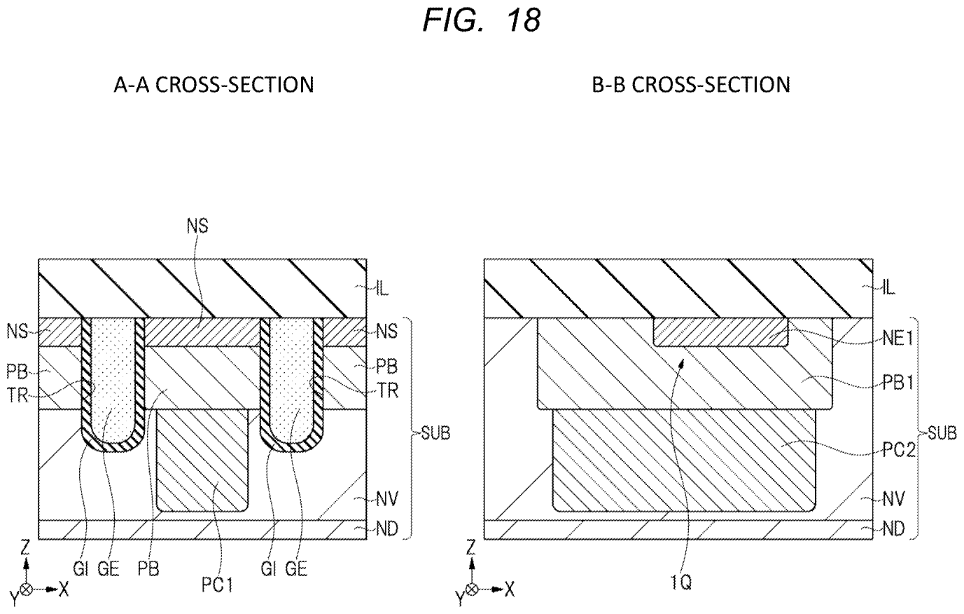

As shown in FIG. 18, the interlayer insulating film IL is formed on the upper surface of the semiconductor substrate SUB in the regions 1A and 2A.

First, a silicon oxide film is formed on the upper surface of the semiconductor substrate SUB, for example, by a CVD method. Next, a BPSG film is formed on the silicon oxide film, for example, by a coating method. Then, a heat treatment is performed on the BPSG film. Then, the interlayer insulating film IL is polished by a CMP (Chemical Mechanical Polishing) method. As a result, the upper surface of the interlayer insulating film IL is flattened.

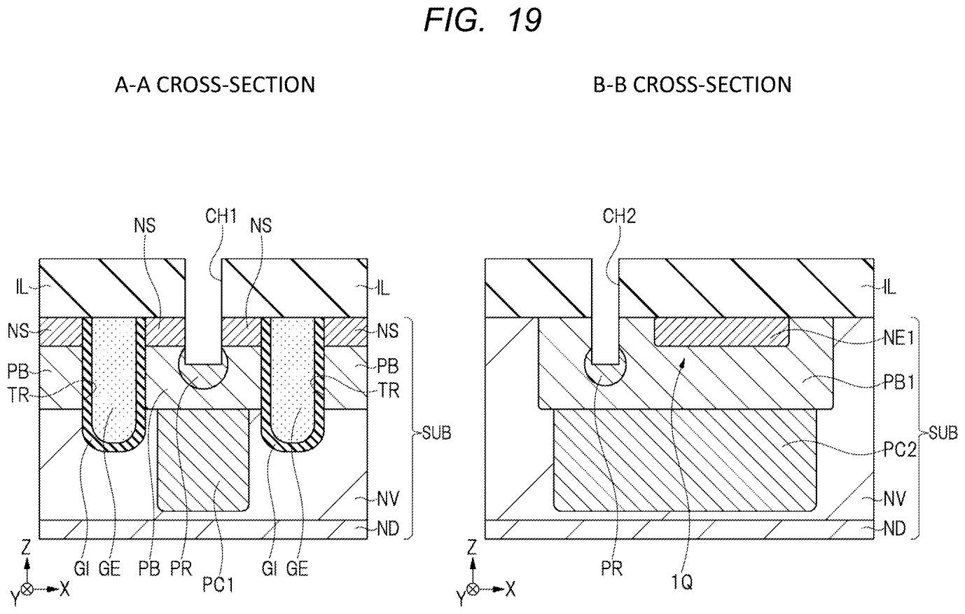

As shown in FIG. 19, first, a hole CH1 is formed in the interlayer insulating film IL, the source region NS, and the body region PB in the region 1A by photolithography technology and anisotropic etching process. The bottom of the hole CH1 is located inside the body region PB. At this time, in the region 2A, a hole CH2 is formed in the interlayer insulating film IL and the base region PB1. The bottom of the hole CH2 is located inside the base region PB1.

Next, within the body region PB at the bottom of the hole CH1, and within the base region PB1 at the bottom of the hole CH2, a p-type high concentration diffusion region PR is formed by introducing, for example, boron (B) by ion-implantation.

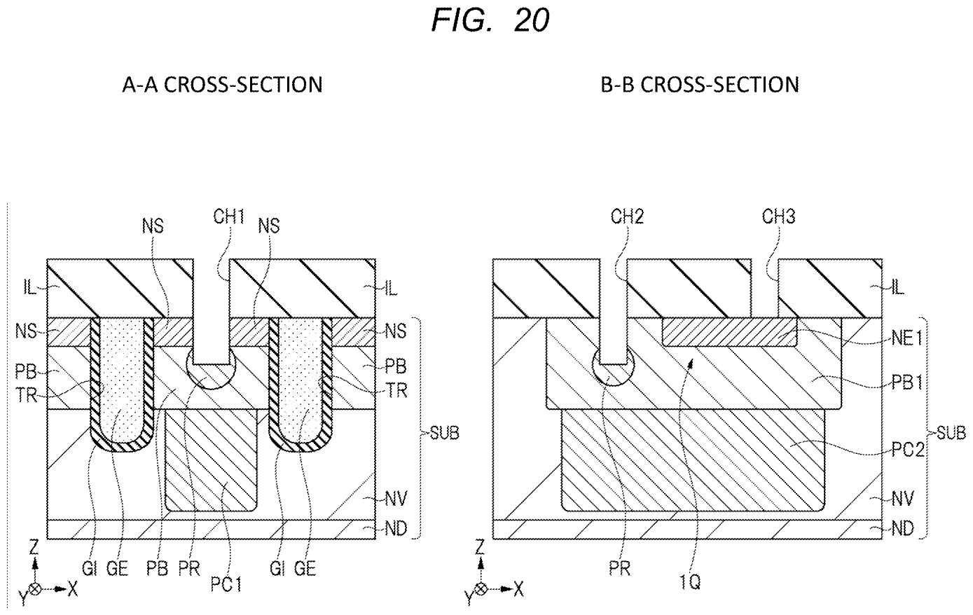

As shown in FIG. 20, a hole CH3 is formed in the interlayer insulating film IL of the region 2A by photolithography technology and anisotropic etching treatment. The hole CH3 reaches the emitter region NE1.

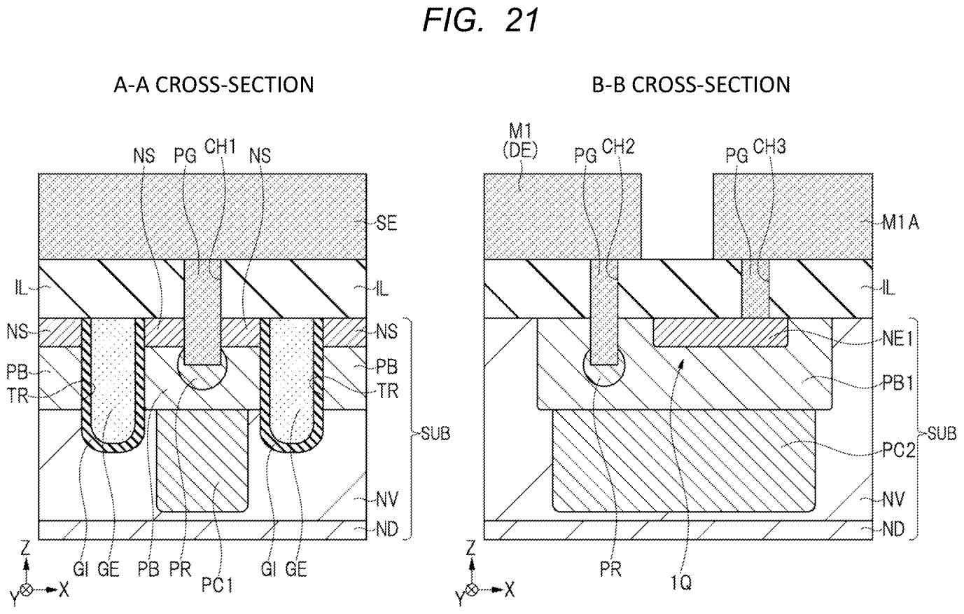

As shown in FIG. 21, a plug PG is formed inside each of the holes CH1 to CH3, and the source electrode SE, the wiring M1, and the wiring M1A are formed on the interlayer insulating film IL.

First, a barrier metal film is formed inside each of the holes CH1 to CH3 and on the interlayer insulating film IL, for example, by sputtering. Next, a conductive film is formed on the barrier metal film in each of the holes CH1 to CH3 so as to be embedded, for example, by CVD. Then, the barrier metal film and the conductive film formed outside each of the holes CH1 to CH3 are removed by, for example, anisotropic etching. As a result, a plug PG having the barrier metal film and the conductive film is formed in the interlayer insulating film IL. The barrier metal film is, for example, a laminated film of a titanium film and a titanium nitride film. The conductive film is, for example, a tungsten film.

Next, a barrier metal film and a conductive film are sequentially formed on the interlayer insulating film IL, for example, by sputtering or CVD. Then, by patterning the barrier metal film and the conductive film, the source electrode SE, the wiring M1, and the wiring M1A connected to the plug PG are formed on the interlayer insulating film IL. The barrier metal film is, for example, a TiW film. The conductive film is, for example, an aluminum alloy film to which copper or silicon has been added.

Although not shown here, during the manufacturing step of the hole CH3, holes for the gate electrode GE and the wiring M1 connected to the base region of the temperature sensor transistor, which is the first stage of the Darlington connection, are formed. Also, during the manufacturing step of the plug PG, these holes are also embedded with the plug PG. Also, during the manufacturing step of the source electrode SE, the gate wiring GW is also formed.

Subsequently, the structure shown in FIG. 4 is obtained through the following manufacturing steps.

First, an insulating film, such as polyimide, is formed on the interlayer insulating film IL to cover the source electrode SE, the gate wiring GW, the wiring M1, and the wiring M1A, for example, by a coating method. Next, the opening is formed in the insulating film so that a part of the source electrode SE and a part of the gate wiring GW are exposed. The exposed source electrode SE and the gate wiring GW in the opening become the source pad SP and gate pad GP, respectively. Subsequently, the bottom surface of the semiconductor substrate SUB is polished as necessary. Then, the drain electrode DE is formed under the bottom surface of the semiconductor substrate SUB by a sputtering method.

As described above, in the first embodiment, the manufacturing step required for these when manufacturing the temperature sensor transistors 1Q to 3Q in the region 2A can be shared with the manufacturing step for manufacturing the power MOSFET. Therefore, it is possible to suppress an increase in manufacturing cost.

### Second Embodiment

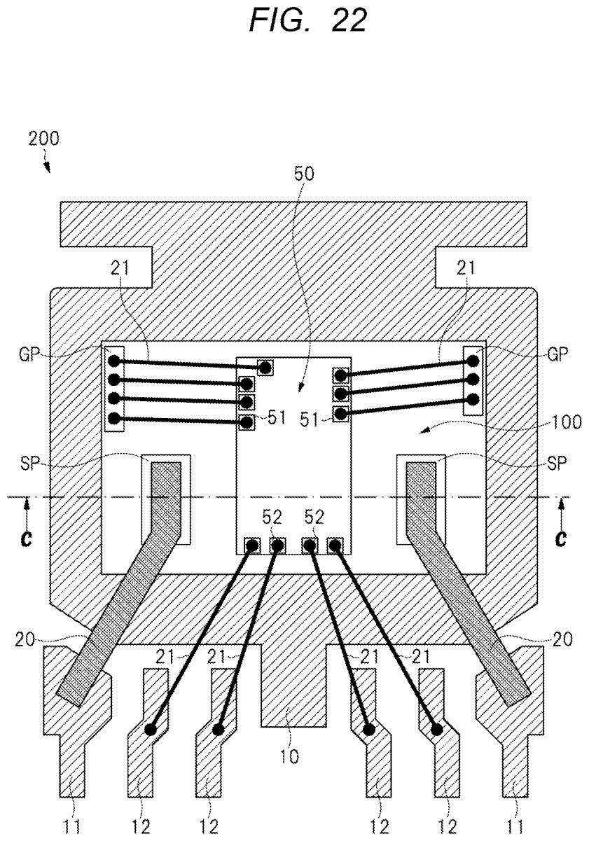

The semiconductor module 200 in the second embodiment will be described below with referring FIGS. 22 to 26. Note that, in the following description, differences from the first embodiment will be mainly described, and the description of overlapping points with the first embodiment will be omitted.

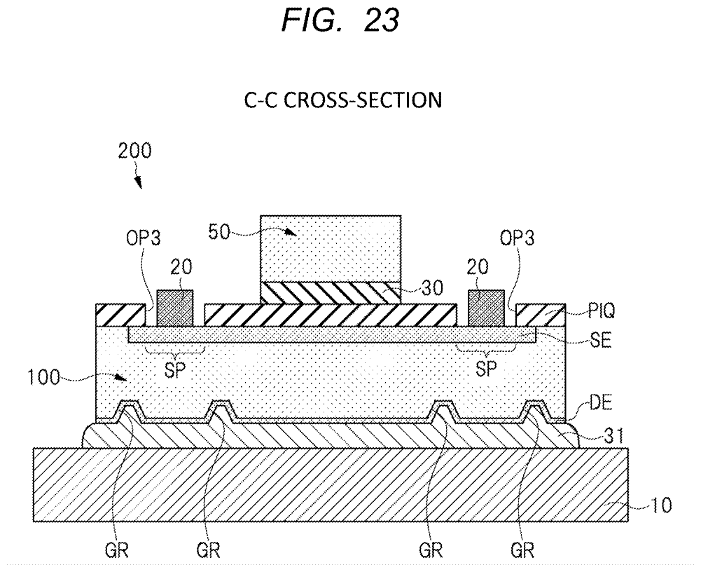

FIG. 22 is a plan view showing the semiconductor module 200. FIG. 23 is a cross-sectional view taken along line C-C in FIG. 22.

As shown in FIGS. 22 and 23, the semiconductor module 200 includes a semiconductor device (semiconductor chip) 100, a semiconductor chip 50, a die pad 10, a plurality of lead terminals 11, a plurality of lead terminals 12, a plurality of wires 20, and a plurality of wires 21. Although not shown, the semiconductor module 200 is sealed with a sealing resin so that a part of each of the die pad 10, the plurality of lead terminals 11, and the plurality of lead terminals 12 is exposed, and is packaged.

The semiconductor device 100 in the second embodiment is the same as the semiconductor device 100 in the first embodiment, but the semiconductor chip 50 having a function to control the semiconductor device 100 is stacked on an upper surface of the semiconductor device 100. In addition, the semiconductor device 100 has increased control pads for obtaining the potentials of transistors necessary to obtain information necessary for control by the semiconductor chip 50. Therefore, the layout of a source pad SP and the gate and control pads GP is different from that in FIG. 1.

In the first embodiment, although not shown in the figure, a source electrode SE and a gate wiring GW are covered with an insulating film PIQ such as a polyimide film. At locations different from where the semiconductor chip 50 is placed, an opening OP3 is provided in a part of the insulating film PIQ. The source electrode SE and the gate wiring GW exposed at the opening OP3 constitute the source pad SP and a gate or control pad GP.

The semiconductor chip 50 is stacked on the upper surface of the semiconductor device 100 via the insulating film PIQ and the insulating resin 30. The insulating resin 30 is, for example, an adhesive tape with heat curing properties.

The semiconductor chip 50 has a control circuit for controlling a gate voltage of a power MOSFET of the semiconductor device 100. A semiconductor module 200, which includes the semiconductor device 100 containing the power MOSFET used as an output circuit and the semiconductor chip 50 containing the control circuit for controlling the gate voltage thereof, is referred to as an IPD (Intelligent Power Device). The control circuit may also include circuits with other functions, such as a boost circuit, an overheat shutdown the control circuit, an overcurrent limit circuit, or a monitor circuit that performs current detection and voltage detection.

Although a detailed explanation is omitted, the semiconductor chip 50 has a multilayer wiring layer for constructing the control circuit and a plurality of pad electrodes 51, 52, which are a part of the wiring of the top layer of the multilayer wiring layer.

The plurality of pad electrodes 51 and the gate pad GP are electrically connected by an external connection member, the wire 21. The wire 21 is formed by ball bonding and is made of, for example, gold. This allows the control circuit to control the gate voltage of the power MOSFET. Also, the plurality of pad electrodes 52 and the plurality of lead terminals 12 are electrically connected by the wire 21. This allows various signals and ground potentials from outside the semiconductor module 200 to be transmitted to the control circuit.

A bottom surface of the semiconductor device 100 is provided on the die pad 10 via a conductive paste 31. The conductive paste 31 is, for example, a silver paste. A drain voltage is supplied from outside the semiconductor module 200 to the die pad 10. Therefore, a drain voltage is supplied to a semiconductor substrate SUB of the semiconductor device 100 via the conductive paste 31 and a drain electrode DE.

The lead terminal 11 and the source pad SP are electrically connected by an external connection member, the wire 20. A source voltage is supplied from outside the semiconductor module 200 to the lead terminal 11. Therefore, a source voltage is supplied to the source electrode SE of the semiconductor device 100 via the wire 20.

The source electrode SE occupies a large part of the planar area of the entire semiconductor device 100, so it is desirable to connect an external connection member to many places of the source electrode SE so that the potential distribution can be as uniform as possible. Therefore, it is desirable to increase the area of the source pad SP and to maximize the contact area between the wire 20 and the source pad SP. For this reason, the wire 20 is formed by wedge bonding. Also, considering the long-term reliability of the joint between the wire 20 and the source pad SP, it is desirable that the metal materials constituting them are of the same type. For example, the wire 20 is made of aluminum or an aluminum alloy to which copper or silicon has been added.

As shown in FIG. 23, a groove GR is formed on the bottom surface of the semiconductor device 100. The groove GR is formed on the bottom surface of the semiconductor substrate SUB. More specifically, the groove GR is formed by processing a part of the drain region ND (n-type silicon substrate) of the semiconductor substrate SUB. The drain electrode DE is formed below the bottom surface of the semiconductor substrate SUB along the shape of the groove GR. When the semiconductor device 100 is placed on the die pad 10, the inside of the groove GR is filled with the conductive paste 31.

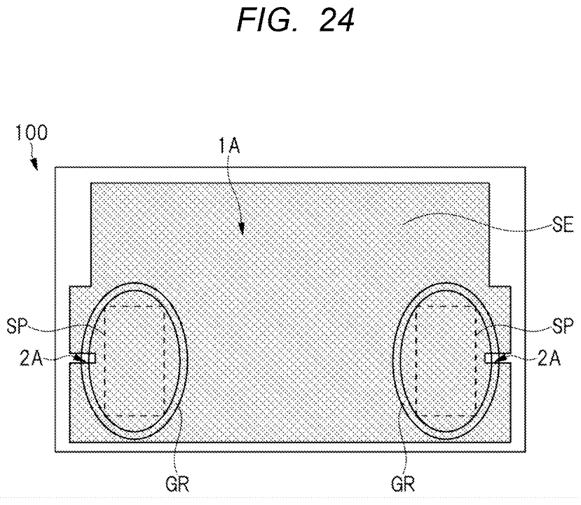

FIG. 24 shows the layout of the source electrode SE, and shows the planar positional relationship of each of the source pad SP, the groove GR, and the region 2A (a sense MOSFET for current monitoring). The sense MOSFET has the same structure as the power MOSFET in region 1A and is provided between the source pad SP of the power MOSFET and an outer edge of the semiconductor device 100. The sense MOSFET also serves to monitor the current value of the power MOSFET.

As shown in FIG. 24, the region 2A where the sense MOSFET for current monitoring is formed is provided between the source pad SP and an outer edge (outer edge of the semiconductor substrate SUB) of the semiconductor device 100. For example, if the region 2A is provided in the center of the semiconductor device 100, it is necessary to route the wiring for connecting to the sense MOSFET for current monitoring. This can cause layout problems, such as the region 1A where the power MOSFET is formed being divided by the region 2A.

If the region 2A is provided around the source pad SP and the outer edge of the semiconductor device 100, the region 1A will not be divided and the wiring can be routed to a minimum. Therefore, the region 1A can be laid out efficiently, and it becomes easier to secure the cell area of the entire power MOSFET.

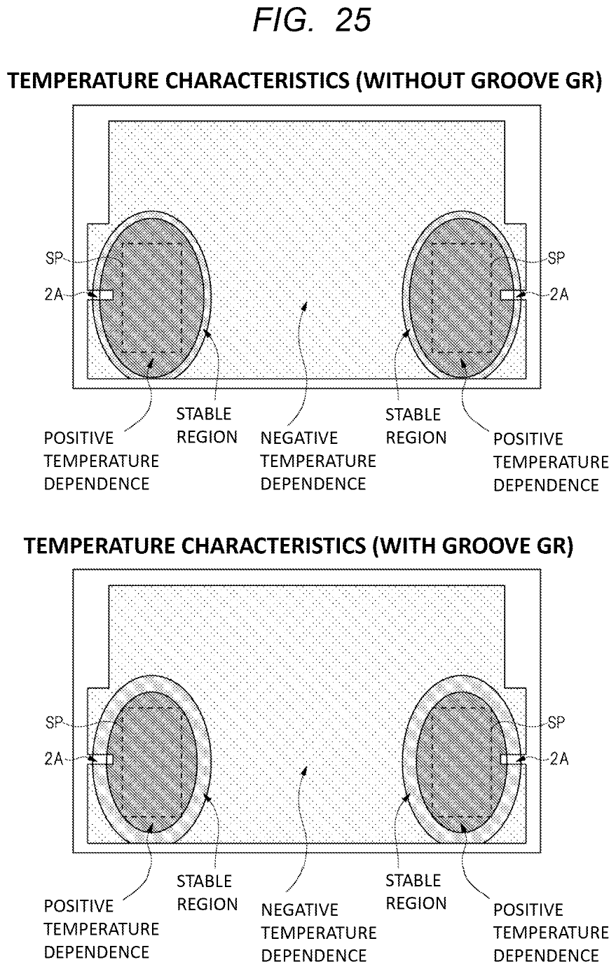

As shown in FIG. 24, the groove GR is formed around the source pad SP in a plan view. In other words, the groove GR is formed on the source pad SP side around the region 2A. The reason for this will be explained with referring FIG. 25.

FIG. 25 schematically shows the temperature characteristics when the wire 20 is connected to the source pad SP. Since the sense MOS transistor is formed by the metal region and the silicon region, the proportion of the metal wiring occupied at the location near the source pad SP and the location away from it is different, resulting in different temperature dependencies of the current value. For example, the area centered on the connection position of the wire 20 becomes an area with a positive temperature dependence of the current value of the sense MOSFET, and the farther away from the connection position of the wire 20, the area with a negative temperature dependence. The stable region is a region with no (or less) temperature dependence in between. Therefore, it is good to place the sense MOSFET here.

Generally, in metals and semimetals, as the temperature rises, the thermal motion of metal atoms makes it difficult for electrons to move. As the temperature rises, the thermal vibration of the atomic nucleus increases, hindering the conduction of electrons and increasing electrical resistance.

On the other hand, in semiconductors, the thermal vibration of the atomic nucleus also increases. However, these originally have few electrons or holes related to conduction. Therefore, as the temperature rises, electrons or holes transition from the filled band to the conduction band, increasing the number of electrons or holes and reducing electrical resistance. In other words, the temperature characteristics are reversed between metals and semimetals and semiconductors.

The stable region in FIG. 25 is a region where the balance between metals and semiconductors is achieved. As shown in FIG. 25, by forming the groove GR on the bottom surface (bottom surface of the semiconductor substrate SUB) of the semiconductor device 100 on the source pad side around the region 2A, the stable region can be expanded. The sense MOSFET is formed near the groove GR and in the stable region, which can reduce the temperature dependence of the current value of the sense MOSFET and improve reliability. The sense MOSFET may be provided at a position overlapping the groove GR in a plan view.

The wire 20 is formed by wedge bonding, but in wedge bonding, the position where the wire 20 contacts the source pad SP is likely to shift. If such a shift in the contact position occurs, the position of the stable region will also shift. However, as described above, by expanding the stable region with the groove GR, even if the position of the stable region shifts slightly, a temperature sensor transistor is likely to be located in the stable region. Therefore, it is easier to ensure the reliability of temperature detection.

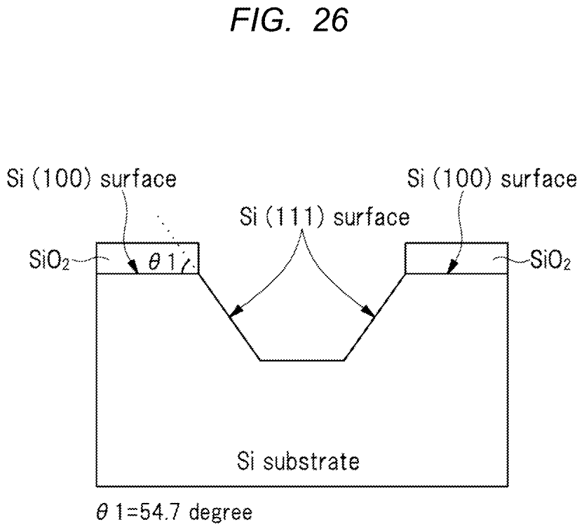

The manufacturing method for forming the groove GR will be explained with referring FIG. 26. The groove GR can be formed using an etching solution containing tetramethylammonium hydroxide (TMAH).

FIG. 26 shows a case where the crystal plane of the surface of the semiconductor substrate made of silicon is the (100) plane. A silicon oxide film is selectively formed on the surface of the semiconductor substrate, and an etching process is performed using an etching solution containing TMAH with the silicon oxide film as a mask. This forms the groove in the semiconductor substrate. After a certain time has passed, the crystal plane of the side surface of the groove becomes the (111) plane, and the side surface of the groove becomes a flat surface. In FIG. 26, the angle θ1 formed by the surface of the semiconductor substrate and the side surface of the groove is 54.7 degrees.

In the second embodiment, such a manufacturing method can be used to form the groove GR on the bottom surface of the semiconductor substrate SUB. The manufacturing step for forming the groove GR is performed after the manufacturing step of FIG. 21. Specifically, the groove GR can be formed after forming the insulating film PIQ on the interlayer insulating film IL and polishing the bottom surface of the semiconductor substrate SUB as necessary, and before forming the drain electrode DE under the bottom surface of the semiconductor substrate SUB.

Although the present invention has been described in detail based on the above-described embodiments, the present invention is not limited to the above-described embodiments, and can be variously modified without departing from the gist thereof.

What is claimed is:

1. A method for manufacturing a semiconductor device having a first region where a MOSFET is formed and a second region where a first temperature sensor transistor is formed, comprising steps of:
(a) providing a semiconductor substrate of a first conductivity type having an upper surface and a bottom surface;
(b) forming a trench on the upper surface of the semiconductor substrate in the first region;
(c) forming a gate dielectric film inside the trench;
(d) forming a gate electrode inside the trench via the gate dielectric film;
(e) in the first region, forming a body region of a second conductivity type opposite to the first conductivity type in the semiconductor substrate close to the upper surface of the semiconductor substrate so as to be shallower than a depth of the trench, and in the second region, forming a first base region of the second conductivity type in the semiconductor substrate;
(f) forming a source region of the first conductivity type in the body region, and forming a first emitter region of the first conductivity type in the first base region; and
(g) in the first region, forming a first column region of the second conductivity type in the semiconductor substrate located below the body region, and in the second region, forming a second column region of the second conductivity type in the semiconductor substrate located below the first base region, wherein
the MOSFET includes the semiconductor substrate of the first region, the trench, the gate dielectric film, the gate electrode, the body region, the source region, and the first column region, and
the first temperature sensor transistor includes the semiconductor substrate of the second region, the first base region, the first emitter region, and the second column region.

2. The method for manufacturing the semiconductor device according to claim 1, wherein
the first column region is in contact with the body region,
the second column region is in contact with the first base region,
an impurity concentration of the first column region is higher than an impurity concentration of the body region,
an impurity concentration of the second column region is higher than an impurity concentration of the first base region.

3. The method for manufacturing the semiconductor device according to claim 2, wherein
the second column region is included within the first base region in a plan view, and
the first emitter region is included within the second column region in a plan view.

4. The method for manufacturing the semiconductor device according to claim 1, further comprising steps of:
(h) in the first region and the second region, forming an interlayer insulating film on the upper surface of the semiconductor substrate;
(i) forming a gate wiring, a source electrode, a first wiring, and a second wiring on the interlayer insulating film; and
(j) in the first region and the second region, forming a drain electrode under the bottom surface of the semiconductor substrate; wherein
the gate wiring is electrically connected to the gate electrode,
the source electrode is electrically connected to the body region and the source region,
the drain electrode is electrically connected to the semiconductor substrate,
the first wiring is electrically connected to the first emitter region, and
the second wiring is electrically connected to the first base region.

5. The method for manufacturing the semiconductor device according to claim 4, wherein
the second wiring is electrically connected to the drain electrode.

6. The method for manufacturing the semiconductor device according to claim 4, wherein
in the step of (e), in the second region, a second base region of the second conductivity type and a third base region of the second conductivity type are formed in the semiconductor substrate,
in the step of (f), a second emitter region of the first conductivity type is formed in the second base region, and a third emitter region of the first conductivity type is formed in the third base region,
in the step of (g), in the second region, a third column region of the second conductivity type is formed in the semiconductor substrate located below the second base region, and in the second region, a fourth column region of the second conductivity type is formed in the semiconductor substrate located below the third base region,
in the step of (i), a third wiring and a fourth wiring are formed on the interlayer insulating film,
the second wiring is electrically connected to the first base region and the second emitter region,
the third wiring is electrically connected to the second base region and the third emitter region,
the fourth wiring is electrically connected to the third base region and the drain electrode,
in the second region, a plurality of temperature sensor transistors is formed including at least the first temperature sensor transistor, a second temperature sensor transistor, and a third temperature sensor transistor,
the second temperature sensor transistor includes the semiconductor substrate of the second region, the second base region, the second emitter region, and the third column region, and
the third temperature sensor transistor includes the semiconductor substrate of the second region, the third base region, the third emitter region, and the fourth column region.

7. A semiconductor device having a first region where a MOSFET is formed and a second region where a first temperature sensor transistor is formed, comprising:
a semiconductor substrate of a first conductivity type having an upper surface and a bottom surface,
a trench formed on the upper surface of the semiconductor substrate in the first region,
a gate dielectric film formed inside the trench,
a gate electrode formed inside the trench via the gate dielectric film,
in the first region, a body region of a second conductivity type opposite to the first conductivity type formed in the semiconductor substrate close to the upper surface of the semiconductor substrate so as to be shallower than a depth of the trench,
a source region of the first conductivity type formed in the body region,
in the first region, a first column region of the second conductivity type formed in the semiconductor substrate located below the body region,
in the second region, a first base region of the second conductivity type formed in the semiconductor substrate close to the upper surface of the semiconductor substrate;
a first emitter region of the first conductivity type formed in the first base region, and
a second column region of the second conductivity type formed in the semiconductor substrate located below the first base region, wherein
the MOSFET includes the semiconductor substrate of the first region, the trench, the gate dielectric film, the gate electrode, the body region, the source region, and the first column region, and
the first temperature sensor transistor includes the semiconductor substrate of the second region, the first base region, the first emitter region, and the second column region,
the second column region has a same depth as the first column region, and
an impurity concentration of the second column region is same as an impurity concentration of the first column region.

8. The semiconductor device according to claim 7, wherein
the first column region is in contact with the body region,
the second column region is in contact with the first base region,
the impurity concentration of the first column region is higher than an impurity concentration of the body region,
the impurity concentration of the second column region is higher than an impurity concentration of the first base region.

9. The semiconductor device according to claim 8, wherein
the second column region is included within the first base region in a plan view, and
the first emitter region is included within the second column region in a plan view.

10. The semiconductor device according to claim 7, further comprising:
an interlayer insulating film formed on the upper surface of the semiconductor substrate; and
a gate wiring, a source electrode, a first wiring, and a second wiring formed on the interlayer insulating film;
a drain electrode formed under a bottom surface of the semiconductor substrate, wherein
the gate wiring is electrically connected to the gate electrode,
the source electrode is electrically connected to the body region and the source region,
the drain electrode is electrically connected to the semiconductor substrate,
the first wiring is electrically connected to the first emitter region, and
the second wiring is electrically connected to the first base region.

11. The semiconductor device according to claim 10, wherein
the second wiring is electrically connected to the drain electrode.

12. The semiconductor device according to claim 10, further comprising:
a second base region of the second conductivity type formed in the semiconductor substrate;
a second emitter region of the first conductivity type formed in the second base region;
a third base region of the second conductivity type formed in the semiconductor substrate located below the second base region;
a third emitter region of the first conductivity type formed in the third base region;
a fourth column region of the second conductivity type formed in the semiconductor substrate located below the third base region; and
a third wiring and a fourth wiring formed on the interlayer insulating film, wherein
the second wiring is electrically connected to the first base region and the second emitter region,
the third wiring is electrically connected to the second base region and the third emitter region,
the fourth wiring is electrically connected to the third base region and the drain electrode,
in the second region, a plurality of temperature sensor transistors is formed including at least the first temperature sensor transistor, a second temperature sensor transistor, and a third temperature sensor transistor,
the second temperature sensor transistor includes the semiconductor substrate of the second region, the second base region, the second emitter region, and a third column region,
the third temperature sensor transistor includes the semiconductor substrate of the second region, the third base region, the third emitter region, and the fourth column region,
the third column region and the fourth column region have a same depth as the first column region respectively, and an impurity concentration of the third column region and an impurity concentration of the fourth column region are same as the impurity concentration of the first column region.

13. A semiconductor module comprising:
a first semiconductor chip having a MOSFET and a sense MOSFET; and
a second semiconductor chip stacked on the upper surface of the first semiconductor chip via an insulating film and having a control circuit for controlling a gate voltage of the MOSFET, wherein
the first semiconductor chip has a source electrode electrically connected to the source region of the MOSFET,
an opening is formed in the insulating film at a location different from where the second semiconductor chip is placed,
the source electrode exposed from the opening configures a source pad,
the sense MOSFET has a same structure as the MOSFET and is provided between the source pad of the MOSFET and an outer edge of the first semiconductor chip, and
the sense MOSFET has a function of monitoring a current value of the MOSFET.

14. A semiconductor module according to claim 13, wherein
a groove is formed on a bottom surface of the first semiconductor chip, and
the groove is formed around the source pad in a plan view.

15. A semiconductor module according to claim 14, wherein
the sense MOSFET is provided at a position overlapping the groove in a plan view.

16. A semiconductor module according to claim 14, further comprising:
a die pad, and
a plurality of lead terminals, wherein
the bottom surface of the first semiconductor chip is provided on the die pad via a conductive paste such that inside of the groove is filled with the conductive paste.

17. A semiconductor module according to claim 16, wherein
a first lead terminal among the plurality of lead terminals and the source pad are electrically connected by a first wire, and
the first wire is formed by wedge bonding, and is made of aluminum, or an aluminum alloy contained copper or silicon.

18. A semiconductor module according to claim 17, further comprising:
the second semiconductor chip has a multilayer wiring layer and a pad electrode which is a part of a wiring of a top layer among the multilayer wiring layer,
a second lead terminal among the plurality of lead terminals and the pad electrode are electrically connected by a second wire, and
the second wire is formed by ball bonding, and is made of gold.
